(19) United States
(12) Patent Application Publication
(10) Pub. No.: US 2019/0334127 A1
(43) Pub. Date: Oct. 31, 2019

(54) OLED DISPLAY DEVICE

(71) Applicant: Wuhan China Star Optoelectronics Technology Co., Ltd., Wuhan HB (CN)

(72) Inventors: Xueyun Li, Wuhan (CN); Yuejun Tang, Wuhan (CN)

(21) Appl. No.: 16/096,690

(22) PCT Filed: Sep. 13, 2018
(86) PCT No.: PCT/CN2018/105585

§ 371 Date: Oct. 25, 2018

(30) Foreign Application Priority Data
Apr. 26, 2018 (CN) 201810386918.2

(51) Int. Cl. H01L 51/52; H01L 27/32

(52) U.S. Cl. CPC H01L 51/5281; H01L 27/3232; H01L 51/5253; H01L 51/5259

(57) ABSTRACT

The present invention teaches an OLED display device including a substrate, an OLED device on the substrate, and an anti-reflection layer above the OLED device connected with the substrate. The anti-reflection layer not only may reduce the reflection of ambient light, but also may replace the encapsulation layer of the prior art. The resulted OLED display device then may be thinner and lighter, and the manufacturing process is simpler. The anti-reflection layer may also replace the cover plate of the prior art, making the OLED display device even thinner and further simplifying the manufacturing process of the OLED display device.

### FIELD OF THE INVENTION

The present invention is generally related to the field of display technology, and more particularly to an organic light emitting diode (OLED) display device.

### BACKGROUND OF THE INVENTION

Organic light emitting diode (OLED) display, also called electroluminescence display, is an emerging flat panel display device. It is deemed as the most promising display device by the industry due to its self-illumination, low driving voltage, high lighting efficiency, short response time, enhanced clarity and contrast, nearly 180-degree viewing angle, wide operation temperature range, and the capability to fulfill flexible, large-dimension, full-color display.

An OLED device generally includes a substrate, an anode on the substrate, a hole injection layer on the anode, a hole transport layer on the hole injection layer, a lighting material layer on the hole transport layer, an electron transport layer on the lighting material layer, an electron injection layer on the electron injection layer, and a cathode on the electron injection layer. The operation principle of the OLED device is that light is produced by the injection and combination of electrons and holes as semiconductor and organic lighting material are driven by electrical field. Specifically, an OLED device often uses indium tin oxide (ITO) pixel electrode as the anode and metallic electrode as cathode. Under a specific voltage, electrons and holes are injected into the electron injection layer and the hole injection layer from the anode and cathode. Electrons and holes then move to the lighting material layer through the electron transport layer and the hole transport layer. Electrons and holes meet in the lighting material layer to form excitons and excite lighting molecules. The latter emits visible light through radiation relaxation.

As shown in FIG. 1, existing OLED display device includes a substrate 100, an OLED device 200 on the substrate 100, an encapsulation layer 300 above the OLED device 200, and an encapsulation adhesive 400 between the encapsulation layer 300 and the substrate 100 surrounding the OLED device 200. To avoid the reflection of ambient light to affect the optical quality of the OLED display device, a circular polarization plate 500 is disposed on the encapsulation layer 300 and, to protect the surface of the OLED display device and the circular polarization plate 500, a cover plate 600 is disposed on the circular polarization plate 500. The encapsulation layer 300, the circular polarization plate 500, and the cover plate 600 significantly increase the thickness of the OLED display device, against the goal of reducing the thickness and weight of the OLED display device. They also complicate the manufacturing process.

### SUMMARY OF THE INVENTION

An objective of the present invention is to provide an OLED display device where the encapsulation layer and cover plate of the prior art are replaced by an anti-reflection layer so as to achieve smaller thickness and simplified manufacturing process for OLED display device.

To achieve the objective, the present invention teaches an OLED display device which includes a substrate, an OLED device on the substrate, and an anti-reflection layer above the OLED device connected with the substrate.

The anti-reflection layer is for reducing the reflection of ambient light, and for encapsulating and protecting the OLED device.

The OLED display device further includes an encapsulation adhesive between the anti-reflection layer and the substrate surrounding the OLED device. The anti-reflection layer is connected with the substrate through the encapsulation adhesive.

The OLED display device further includes a desiccant on the substrate between the OLED device and the encapsulation adhesive.

Alternatively, the OLED display device further includes a thin film encapsulation layer between the anti-reflection layer and the substrate covering the OLED device and the substrate. The OLED display device also includes an adhesion layer between the anti-reflection layer and the substrate covering the thin film encapsulation layer. The anti-reflection layer is connected with the substrate through the adhesion layer.

The anti-reflection layer includes a quarter wave plate (QWP) layer, a polarization layer on the QWP layer, and an upper protection layer on the polarization layer.

The anti-reflection layer further includes a lower protection layer between the QWP layer and the polarization layer.

The anti-reflection layer further includes an attachment layer beneath the QWP layer, and a shielding layer beneath the attachment layer.

The anti-reflection layer further includes an attachment layer beneath the QWP layer, and a shielding layer beneath the attachment layer.

The anti-reflection layer further includes an attachment layer beneath the QWP layer, and a half wave plate (HWP) layer beneath the attachment layer.

The upper protection layer is made of triacetate cellulose (TAC) or glasses. The polarization layer is made of polyvinyl alcohol (PVA). The QWP layer is a dual refractivity thin film formed by stretching a polymeric thin film, an alignment film of liquid crystal compound, or a thin film supported by an alignment film of liquid crystal polymer.

The present invention has the following advantages. The OLED display device of the present invention includes a substrate, an OLED device on the substrate, and an anti-reflection layer above the OLED device connected with the substrate. The anti-reflection layer not only may reduce the reflection of ambient light, but also may replace the encapsulation layer of the prior art. The resulted OLED display device then may be thinner and lighter, and the manufacturing process is simpler. The anti-reflection layer may also replace the cover plate of the prior art, making the OLED display device even thinner and further simplifying the manufacturing process of the OLED display device.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a structural schematic diagram showing an existing OLED display device.

FIG. 2 is a structural schematic diagram showing an OLED display device according to an embodiment of the present invention.

FIG. 3 is a structural schematic diagram showing an OLED display device according to another embodiment of the present invention.

FIG. 4 is a structural schematic diagram of an anti-reflection layer according to a first embodiment of the present invention.

FIG. 5 is a structural schematic diagram of an anti-reflection layer according to a second embodiment of the present invention.

FIG. 6 is a structural schematic diagram of an anti-reflection layer according to a third embodiment of the present invention.

FIG. 7 is a structural schematic diagram of an anti-reflection layer according to a fourth embodiment of the present invention.

FIG. 8 is a structural schematic diagram of an anti-reflection layer according to a fifth embodiment of the present invention.

### DETAILED DESCRIPTION OF PREFERRED EMBODIMENTS

The following descriptions for the respective embodiments are specific embodiments capable of being implemented for illustrations of the present invention with referring to appended figures.

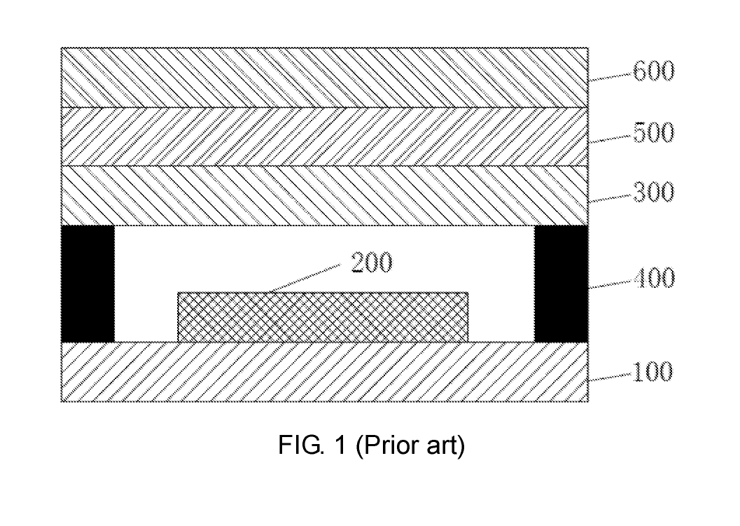

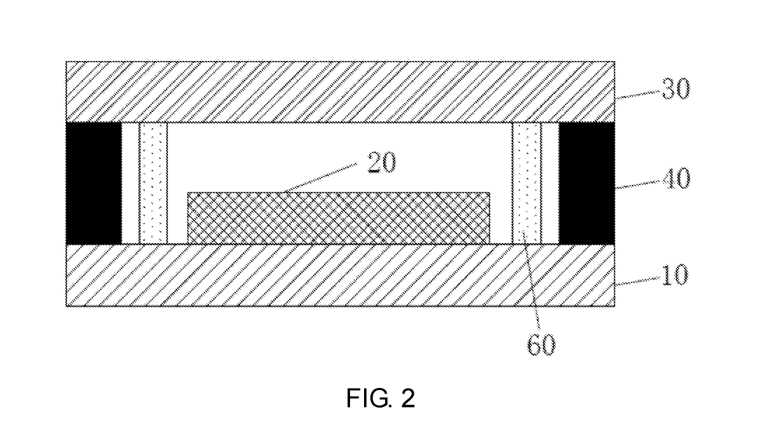

As shown in FIGS. 1 and 2, an organic light emitting diode (OLED) display device according to an embodiment of the present invention includes a substrate 10, an OLED device 20 on the substrate 10, and an anti-reflection layer 30 above the OLED device 20 connected with the substrate 10.

The anti-reflection layer 30 is for reducing the reflection of ambient light, and for encapsulating and protecting the OLED device 20.

It should be noted that, by having the anti-reflection layer 30 above the OLED device 20 connecting the substrate 10, the anti-reflection layer 30 not only may reduce the reflection of ambient light, but also may replace the encapsulation layer of the prior art. The resulted OLED display device then may be thinner and lighter, and the manufacturing process is simpler. The anti-reflection layer 30 may also replace the cover plate of the prior art, making the OLED display device even thinner and further simplifying the manufacturing process of the OLED display device.

As shown in FIG. 2, selectively, the OLED display device further includes encapsulation adhesive 40 between the anti-reflection layer 30 and the substrate 10 surrounding the OLED device 20. The anti-reflection layer 30 is connected with the substrate through the encapsulation adhesive 40.

Furthermore, the OLED display device further includes a desiccant 60 on the substrate 10 between the OLED device 20 and the encapsulation adhesive 40.

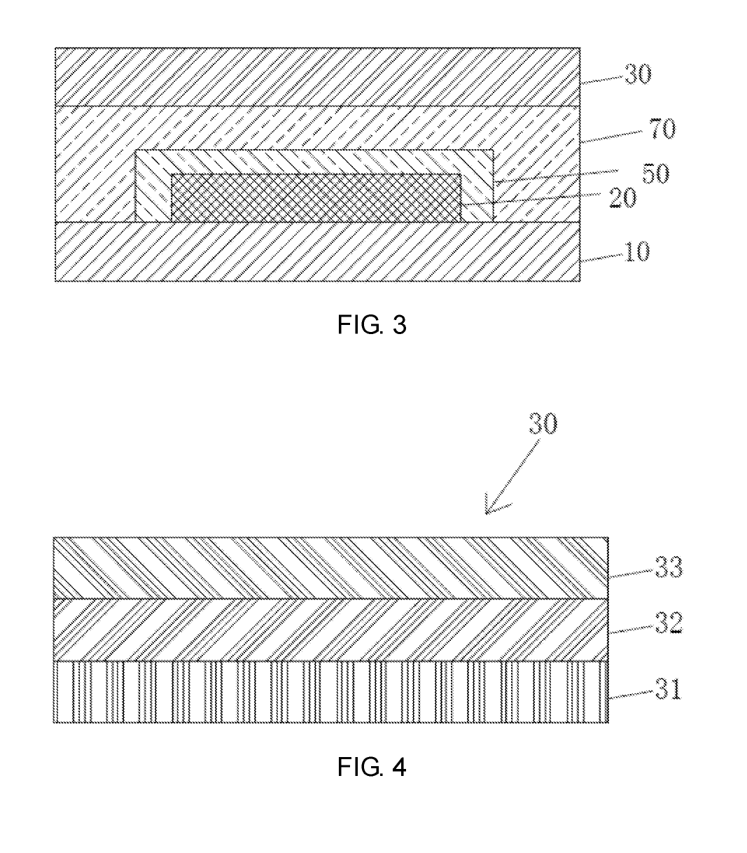

As shown in FIG. 3, in a second embodiment of the present invention, the OLED display device further includes a thin film encapsulation layer 50 between the anti-reflection layer 30 and the substrate 10 covering the OLED device 20 and the substrate 10. The OLED display device also includes an adhesion layer 70 between the anti-reflection layer 30 and the substrate 10 covering the thin film encapsulation layer 50. The anti-reflection layer 30 is connected with the substrate 10 through the adhesion layer 70.

Specifically, the thin film encapsulation layer 50 includes at least an inorganic layer and at least an organic layer alternately stacked together.

Specifically, the specifically 10 is made of one of glasses, metal, polyimide (PI), polycarbonate (PC), polyether sulfones (PES), polyethylene terephthalate (PET), polyethylene naphthalate (PEN), polyarylate (PAR) compound, and fiber reinforced plastics (FRP).

As shown in FIG. 4, a first embodiment of the anti-reflection layer 30 includes a quarter wave plate (QWP) layer 31, a polarization layer 32 on the QWP layer 31, and an upper protection layer 33 on the polarization layer 32. The QWP layer 31 is connected with the substrate 10.

Specifically, the upper protection layer 33 is made of triacetate cellulose (TAC) or glasses. To further protect the anti-reflection layer 30 and the OLED display device, a cover plate may be disposed on the anti-reflection layer 30. The present invention is not limited as such. The cover plate and the upper protection layer 33 may be adhered together through optical adhesive (OCA) or optically transparent resin (OCR).

Specifically, the polarization layer 32 is made of polyvinyl alcohol (PVA).

Specifically, the QWP layer 31 is a dual refractivity thin film formed by stretching a polymeric thin film, an alignment film of liquid crystal compound, or a thin film supported by an alignment film of liquid crystal polymer.

The polymeric thin film is made of at least one of TAC, PC, cyclo-olefin polymer (COP), PVA, polystyrene (PS), polymethyl methacrylate (PMMA), polypropylene (PP), polyolefin, PAR, and polyamide (PA).

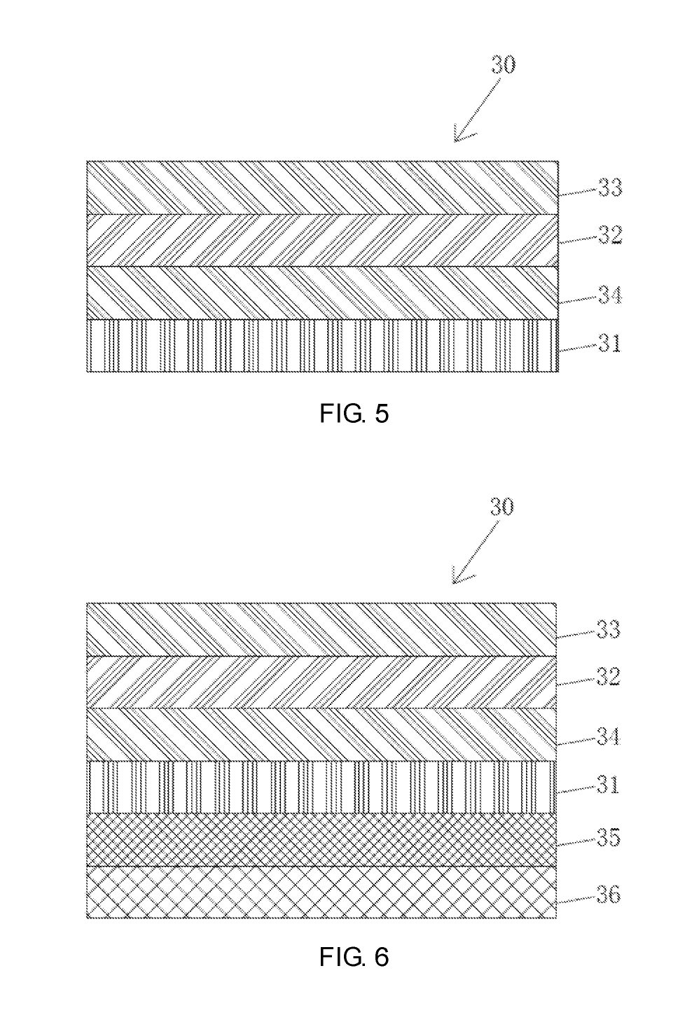

As shown in FIG. 5, a second embodiment of the anti-reflection layer 30 differs from the first embodiment in that the anti-reflection layer 30 further includes a lower protection layer 34 between the QWP layer 31 and the polarization layer 32. The lower protection layer 34 provides additional protection to the polarization layer 32.

Specifically, the lower protection layer 34 is made of a same material as the upper protection layer 33. Of course, the upper and lower protection layers 33 and 34 are not limited TAC or glasses, and may be made of other special material.

As shown in FIG. 6, a third embodiment of the anti-reflection layer 30 differs from the second embodiment in that the anti-reflection layer 30 further includes an attachment layer 35 beneath the QWP layer 31, and a shielding layer 36 beneath the attachment layer 35. The shielding layer 36 is connected with the substrate 10, and provides additional protection to the anti-reflection layer 30. The shielding layer 36 may also prevent moist and oxygen from permeating into the OLED device 20, prolonging the operation life of the OLED device 20.

Specifically, the shielding layer 36 is made of glasses or other watertight or airtight material.

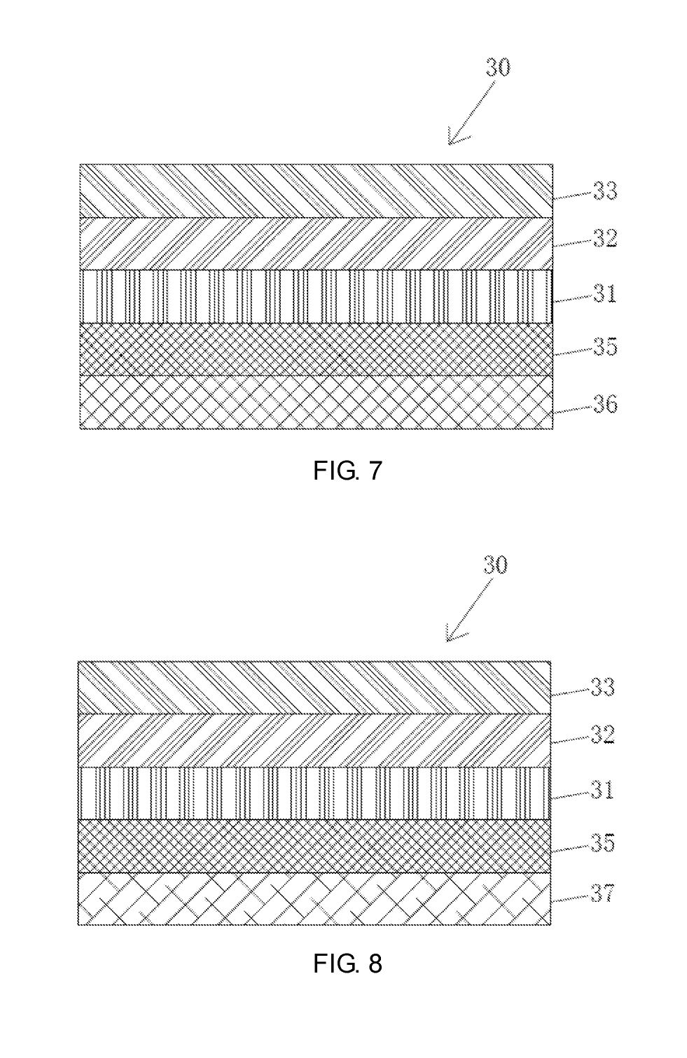

As shown in FIG. 7, a fourth embodiment of the anti-reflection layer 30 differs from the first embodiment in that the anti-reflection layer 30 further includes an attachment layer 35 beneath the QWP layer 31, and a shielding layer 36 beneath the attachment layer 35. The shielding layer 36 is connected with the substrate 10. In the present embodiment, due to the provision of the shielding layer 36, the lower protection layer 34 may be omitted for reducing the thickness of the anti-reflection layer 30. In the meantime, the QWP layer 31 also functions as a phase delayer layer and a protection layer.

Specifically, the shielding layer 36 is made of glasses or other watertight or airtight material.

As shown in FIG. 8, a fifth embodiment of the anti-reflection layer 30 differs from the first embodiment in that the anti-reflection layer 30 further includes an attachment layer 35 beneath the QWP layer 31, and a half wave plate (HWP) layer 37 beneath the attachment layer 35. The HWP layer 37 is connected with the substrate 10, further enhancing the anti-reflection layer 30's effect in reducing the reflection of ambient light.

Specifically, the HWP layer 37 is made of one of TAC, PC, and COP.

As described above, the OLED display device of the present invention includes a substrate, an OLED device on the substrate, and an anti-reflection layer above the OLED device connected with the substrate. The anti-reflection layer not only may reduce the reflection of ambient light, but also may replace the encapsulation layer of the prior art. The resulted OLED display device then may be thinner and lighter, and the manufacturing process is simpler. The anti-reflection layer may also replace the cover plate of the prior art, making the OLED display device even thinner and further simplifying the manufacturing process of the OLED display device.

Above are embodiments of the present invention, which does not limit the scope of the present invention. Any equivalent amendments within the spirit and principles of the embodiment described above should be covered by the protected scope of the invention.

What is claimed is:

1. An organic light emitting diode (OLED) display device, comprising a substrate, an OLED device on the substrate, and an anti-reflection layer above the OLED device connected with the substrate,
wherein the anti-reflection layer is for reducing the reflection of ambient light, and for encapsulating and protecting the OLED device.

2. The OLED display device according to claim 1, further comprising an encapsulation adhesive between the anti-reflection layer and the substrate surrounding the OLED device, wherein the anti-reflection layer is connected with the substrate through the encapsulation adhesive.

3. The OLED display device according to claim 2, further comprising a desiccant on the substrate between the OLED device and the encapsulation adhesive.

4. The OLED display device according to claim 1, further comprising a thin film encapsulation layer between the anti-reflection layer and the substrate covering the OLED device and the substrate, and an adhesion layer between the anti-reflection layer and the substrate covering the thin film encapsulation layer, wherein the anti-reflection layer is connected with the substrate through the adhesion layer.

5. The OLED display device according to claim 1, wherein the anti-reflection layer comprises a quarter wave plate (QWP) layer, a polarization layer on the QWP layer, and an upper protection layer on the polarization layer.

6. The OLED display device according to claim 5, wherein the anti-reflection layer further comprises a lower protection layer between the QWP layer and the polarization layer.

7. The OLED display device according to claim 6, wherein the anti-reflection layer further comprises an attachment layer beneath the QWP layer, and a shielding layer beneath the attachment layer.

8. The OLED display device according to claim 5, wherein the anti-reflection layer further comprises an attachment layer beneath the QWP layer, and a shielding layer beneath the attachment layer.

9. The OLED display device according to claim 5, wherein the anti-reflection layer further comprises an attachment layer beneath the QWP layer, and a half wave plate (HWP) layer beneath the attachment layer.

10. The OLED display device according to claim 5, wherein the upper protection layer is made of triacetate cellulose (TAC) or glasses; the polarization layer is made of polyvinyl alcohol (PVA); and the QWP layer is a dual refractivity thin film formed by stretching a polymeric thin film, an alignment film of liquid crystal compound, or a thin film supported by an alignment film of liquid crystal polymer.
